(19) United States
(12) Patent Application Publication
(10) Pub. No.: US 2013/0214289 A1
(43) Pub. Date: Aug. 22, 2013

(54) Short-Resistant Metal-Gate MOS Transistor and Method of Forming the Transistor

(71) Applicant: TEXAS INSTRUMENTS INCORPORATED, (US)

(72) Inventor: Manoj Mehrotra, Plano, TX (US)

(73) Assignee: TEXAS INSTRUMENTS INCORPORATED, Dallas, TX (US)

(21) Appl. No.: 13/658,785

(22) Filed: Oct. 23, 2012

Related U.S. Application Data
(60) Provisional application No. 61/599,570, filed on Feb. 16, 2012.

(51) Int. Cl. H01L 29/78; H01L 21/336

(52) U.S. Cl. 257/77; 438/299; 257/E29.255; 257/E21.409

(57) ABSTRACT

A protective cap is formed on the metal gate of a MOS transistor to protect the metal gate during an etch that forms a source contact opening and a drain contact opening. The protective cap also electrically isolates the source metal contact and the drain metal contact from the metal gate.

This application claims benefit from Provisional Application No. 61/599,570 filed on Feb. 16, 2012 for Manoj Mehrotra.

### BACKGROUND OF THE INVENTION

1. Field of the Invention

The present invention relates to metal-gate MOS transistors and, more particularly, to a short-resistant metal-gate MOS transistor and a method of forming the transistor.

2. Description of the Related Art

A metal oxide semiconductor (MOS) transistor is a well-known semiconductor device which can be implemented as either an n-channel (NMOS) device or a p-channel (PMOS) device. A MOS transistor has spaced-apart source and drain regions, which are separated by a channel, and a gate that lies over, and is insulated from, the channel by a gate dielectric layer. A metal-gate MOS transistor is a type of MOS transistor that utilizes a metal gate and a high-k gate dielectric layer.

FIG. 1 shows a cross-sectional view that illustrates a prior-art metal-gate MOS transistor 100. As shown in FIG. 1, MOS transistor 100 includes a semiconductor body 110. Semiconductor body 110, in turn, includes a single-crystal-silicon substrate region 112, and a trench isolation structure 114 that touches substrate region 112.

In addition, semiconductor body 110 includes a source 120 and a drain 122 that each touch substrate region 112. The source 120 and drain 122 each has a conductivity type that is the opposite of the conductivity type of substrate region 112. Source 120 includes a lightly-doped region 120L, and a heavily-doped region 120H. Similarly, drain 122 includes a lightly-doped region 122L, and a heavily-doped region 122H. Further, substrate region 112 has a channel region 124 that lies between source 120 and drain 122.

As further shown in FIG. 1, MOS transistor 100 includes a high-k gate dielectric structure 126 that touches and lies over channel region 124, and a metal gate 130 that touches gate dielectric structure 126 and lies over channel region 124. MOS transistor 100 also includes a sidewall spacer 132 that touches high-k gate dielectric structure 126 and laterally surrounds gate 130.

MOS transistor 100 further includes an etch stop layer 136 that touches sidewall spacer 132, and a first dielectric layer 140 that touches and lies over etch stop layer 136. MOS transistor 100 additionally includes an etch stop layer 142 that touches and lies over first dielectric layer 140. MOS transistor 100 also includes a second dielectric layer 144 that touches and lies over etch stop layer 142. Etch stop layer 136, first dielectric layer 140, etch stop layer 142, and second dielectric layer 144 are each non-conductive.

In addition, MOS transistor 100 includes a source metal contact 150 that extends through second dielectric layer 144, etch stop layer 142, first dielectric layer 140, and etch stop layer 136 to touch and make an electrical connection to source 120, and a drain metal contact 152 that extends through second dielectric layer 144, etch stop layer 142, first dielectric layer 140, and etch stop layer 136 to touch and make an electrical connection to drain 122.

MOS transistor 100 further includes a gate metal contact 154 that extends through second dielectric layer 144 and etch stop layer 142 to touch and make an electrical connection with metal gate 130. Metal gate contact 154 is shown with dashed lines because gate metal contact 154 lies in a cross-sectional plane that lies behind the cross-sectional plane of FIG. 1.

The threshold voltage of a transistor is the gate voltage required to form an inversion layer at the top surface of the channel region that is sufficient to allow a current to flow from the source region to the drain region. In the case of an NMOS transistor, n-type dopant atoms form the inversion layer, while p-type dopant atoms form the inversion layer in the case of a PMOS transistor.

In operation, with respect to NMOS transistors, when a positive drain-to-source voltage V_{DS} is present, and the gate-to-source voltage V_{GS} is more positive than the threshold voltage, the NMOS transistor turns on and electrons flow from the source region to the drain region. When the gate-to-source voltage V_{GS} is more negative than the threshold voltage, the MOS transistor turns off and no electrons (other than a very small leakage current) flow from the source region to the drain region.

With respect to PMOS transistors, when a negative drain-to-source voltage V_{DS} is present, and the gate-to-source voltage V_{GS} is more negative than the threshold voltage, the PMOS transistor turns on and holes flow from the source region to the drain region. When the gate-to-source voltage V_{GS} is more positive than the threshold voltage, the PMOS transistor turns off and no holes (other than a very small leakage current) flow from the source region to the drain region.

FIGS. 2A-2N show cross-sectional views that illustrate a method 200 of forming a prior-art metal-gate MOS transistor. As shown in FIG. 2A, method 200 utilizes a partially-completed transistor structure 208 that includes a semiconductor body 210. Semiconductor body 210, in turn, includes a single-crystal-silicon substrate region 212 and a trench isolation structure 214 that touches substrate 212.

As further shown in FIG. 2A, method 200 begins by forming a gate dielectric layer 216 that touches and lies over substrate region 212. After this, a polycrystalline-silicon gate layer 218 is formed to touch and lie over gate dielectric layer 216. Next, a patterned mask 220 is formed on gate layer 218.

As shown in FIG. 2B, after patterned mask 220 has been formed, the exposed regions of gate layer 218 and gate dielectric layer 216 are etched away in a conventional manner to expose the top surface of substrate region 212 and form a gate structure 221. Gate structure 221, in turn, includes a gate dielectric structure 222 that touches and lies above substrate region 212, and a gate 224 that touches and lies over gate dielectric structure 222. Alternately, a portion of gate dielectric layer 216 can remain after the etch as illustrated by the dashed lines in FIG. 2B. In this case, gate structure 221 includes gate dielectric layer 216 and gate 224. Following the etch, patterned mask 220 is removed in a conventional manner.

As shown in FIG. 2C, after patterned mask 220 has been removed, a dopant is implanted into substrate region 212 to form spaced-apart lightly-doped regions 230 and 232. The lightly-doped regions 230 and 232 have a conductivity type that is opposite to the conductivity type of substrate region 212.

As shown in FIG. 2D, after the lightly-doped regions 230 and 232 have been formed, a thin layer of oxide is formed, followed by the deposition of a thicker layer of nitride. Following this, the nitride layer and the thin layer of oxide are anisotropically etched until the top surface of gate 224 is exposed to form a side wall spacer 234.

As shown in FIG. 2E, after side wall spacer 234 has been formed, a dopant is implanted into substrate region 212 and the lightly-doped regions 230 and 232 to form spaced-apart heavily-doped regions 236 and 238. The heavily-doped regions 236 and 238 each have a conductivity type that is opposite to the conductivity type of substrate region 212.

Lightly-doped region 230 and heavily-doped region 236 form a source 240, while lightly-doped region 232 and heavily-doped region 238 form a drain 242. The source and drain regions 240 and 242 form a channel region 244 in substrate region 212 that lies between and separates the source and drain regions 240 and 242.

As shown in FIG. 2F, after the source and drain regions 240 and 242 have been formed, an etch stop layer 245 is formed to touch and lie over gate 224, sidewall spacer 234, source region 240, and drain region 242. Following the formation of etch stop layer 245, a dielectric layer 246 is formed on etch stop layer 245.

As shown in FIG. 2G, after dielectric layer 246 has been formed, dielectric layer 246 is planarized until the top surface of etch stop layer 245 has been exposed. Next, etch stop layer 245 and dielectric layer 246 are planarized until the top surface of gate 224 has been exposed. The planarization forms an etch stop structure 247 that touches sidewall spacer 234, and a dielectric structure 248 that touches etch stop structure 247.

As shown in FIG. 2H, after the top surface of gate 224 has been exposed, gate 224 is removed using conventional etchants and procedures. Next, gate dielectric structure 222 is removed using conventional etchants and procedures to form an opening 250 that exposes the top surface of channel region 244.

As shown in FIG. 2I, after opening 250 has been formed, a high-k dielectric layer 252 is formed to line opening 250 and touch the top surface dielectric structure 248. Next, a metal layer 254 is deposited to touch high-k dielectric layer 252 and fill up opening 250. As shown in FIG. 2J, after metal layer 254 has been deposited, metal layer 254 and high-k dielectric layer 252 are planarized until the top surface of dielectric structure 248 has been exposed. The planarization forms a metal gate 260 and a high-k dielectric structure 262.

As shown in FIG. 2K, after metal gate 260 and high-k dielectric structure 262 have been formed, an etch stop layer 264 is formed to touch dielectric structure 248, metal gate 260, and high-k dielectric structure 262. Following the formation of etch stop layer 264, a dielectric layer 266 is formed on etch stop layer 264. After dielectric layer 266 has been formed, a source/drain patterned mask 270 is formed on dielectric layer 266.

As shown in FIG. 2L, after source/drain patterned mask 270 has been formed, the exposed regions of dielectric layer 266, etch stop layer 264, dielectric structure 248, and etch stop structure 247 are etched away to form a source contact opening 272 that exposes the top surface of source 240, and a drain contact opening 274 that exposes the top surface of drain 242. Source/drain patterned mask 270 is then removed.

After source/drain patterned mask 270 has been removed, a gate patterned mask is conventionally formed on dielectric layer 266. After the gate patterned mask has been formed, the exposed regions of dielectric layer 266 and etch stop layer 264 are etched away in a conventional manner to form a gate contact opening (not shown) that exposes the top surface of gate 260. The gate patterned mask is then removed.

As shown in FIG. 2M, after the gate patterned mask has been removed, a source silicide region 276 is formed on the top surface of source 240, and a drain silicide region 278 is formed on the top surface of drain 242. Next, a barrier metal layer 280 is deposited on dielectric layer 266 to line source contact opening 272 and touch source silicide region 276, line drain contact opening 274 and touch drain silicide region 278, and line the gate contact opening and touch gate 260. Following this, a metal layer 282 is deposited on barrier metal layer 280 to fill up the source contact opening 272, the drain contact opening 274, and the gate contact opening.

As shown in FIG. 2N, after metal layer 282 has been deposited, metal layer 282 and barrier metal layer 280 are planarized until the top surface of dielectric layer 266 is exposed. The planarization forms a source metal contact 284 that touches source 240, a drain metal contact 286 that touches drain 242, and a gate metal contact (not shown) that touches gate 260. Following this, method 200 continues with conventional steps.

FIG. 3 shows a cross-sectional view that illustrates a prior-art metal-gate MOS transistor 300. Metal-gate MOS transistor 300 is similar to metal-gate MOS transistor 100 and, as a result, utilizes the same reference numerals to designate the structures that are common to both transistors 100 and 300.

As shown in FIG. 3, metal-gate MOS transistor 300 differs from metal-gate MOS transistor 100 in that metal-gate MOS transistor 300 utilizes a semiconductor body 310 in lieu of semiconductor body 110. Semiconductor body 310, in turn, is the same as semiconductor body 110 except that semiconductor body 310 utilizes a heavily-doped epitaxially-grown structure 312 in lieu of heavily-doped single-crystal-silicon region 120H, and a heavily-doped epitaxially-grown structure 314 in lieu of heavily-doped single-crystal-silicon region 122H. The epitaxially-grown structures 312 and 314 have a conductivity type that is opposite to the conductivity type of substrate region 112.

Thus, in metal-gate MOS transistor 300, lightly-doped region 120L and heavily-doped epitaxially-grown structure 312 form source 120, while lightly-doped region 122L and heavily-doped epitaxially-grown structure 314 form drain 122. The epitaxially-grown structures 312 and 314 can be implemented with, for example, silicon germanium (PMOS) or silicon carbide (NMOS). MOS transistor 300 operates substantially the same as MOS transistor 100.

FIGS. 4A-4C show cross-sectional views that illustrate a method 400 of forming a prior-art metal-gate MOS transistor. Method 400 is the same as method 200 up through the formation of sidewall spacer 234 shown in FIG. 2D. As shown in FIG. 4A, after side wall spacer 234 has been formed, a patterned mask 408 is formed on gate 224. Following this, the exposed portions of substrate region 212 and the lightly-doped regions 230 and 232 are etched to form a source opening 410 and a drain opening 412.

As shown in FIG. 4B, after source opening 410 and drain opening 412 have been formed, a structure 414 is epitaxially grown in source opening 410 at the same time that a structure 416 is epitaxially grown in drain opening 412. The epitaxially-grown structures 414 and 416 each have a conductivity type that is opposite to the conductivity type of substrate region 212, and can be implemented with, for example, silicon germanium (PMOS) or silicon carbide (NMOS).

As shown in FIG. 4C, after the epitaxially-grown structures 414 and 416 have been formed, etch stop layer 245 is formed on gate 224, sidewall spacer 234, and the epitaxially-grown structures 414 and 416 in the same manner that etch stop layer 245 was formed in method 200. Following this, method 400 is the same as method 200, and continues with the formation of dielectric layer 246.

One of the problems with both method 200 and method 400 is that when the source and drain contact openings 272 and 274 are misaligned, the source contact opening 272 can expose both a portion of gate 260 and source 240, or the drain contact opening 274 can expose both a portion of gate 260 and drain 242.

In either case, when the source and drain metal contacts 284 and 286 are subsequently formed, the source 240 and gate 260, or the drain 242 and gate 260 will be shorted together, thereby rendering the transistor unusable. Thus, there is a need for a short-resistant metal-gate MOS transistor that can tolerate misalignment errors.

### SUMMARY OF THE INVENTION

The present invention provides a short-resistant metal-gate MOS transistor and a method of forming the transistor. A semiconductor structure of the present invention includes a semiconductor material that has a conductivity type, a source that touches the semiconductor material, and a drain that touches the semiconductor material. The source and drain each has a conductivity type that is opposite to the conductivity type of the semiconductor material. The drain lies spaced apart from the source. The semiconductor structure also includes a channel region of the semiconductor material that lies between the source and the drain. The semiconductor structure also includes a gate dielectric structure that touches and lies over the channel region, and a gate that touches the gate dielectric structure and lies over the channel region. The semiconductor structure further includes a protective cap that touches and lies over the gate, and a non-conductive sidewall spacer that touches the gate dielectric structure and laterally surrounds both the gate and the protective cap.

A method of forming a semiconductor structure includes forming a first gate structure that touches a semiconductor material. The semiconductor material has a conductivity type. The method also includes forming a source and a drain that touch the semiconductor material. The source and the drain each has a conductivity type that is opposite the conductivity type of the semiconductor material. The method additionally includes forming a first non-conductive structure that touches and lies over the source and the drain. The method further includes removing the first gate structure to form an opening after the first non-conductive structure has been formed, and forming a second gate structure in the opening to touch the semiconductor material. In addition, the method include etching the second gate structure to form a third gate structure, and forming a protective cap that touches and lies over the third gate structure.

A better understanding of the features and advantages of the present invention will be obtained by reference to the following detailed description and accompanying drawings which set forth an illustrative embodiment in which the principals of the invention are utilized.

### BRIEF DESCRIPTION OF THE DRAWINGS

FIG. 1 is a cross-sectional view illustrating a prior-art metal-gate MOS transistor 100.

FIGS. 2A-2N are cross-sectional views illustrating a method 200 of forming a prior-art metal-gate MOS transistor.

FIG. 3 is a cross-sectional view illustrating a prior-art metal-gate MOS transistor 300.

FIGS. 4A-4C are cross-sectional views illustrating a method 400 of forming a prior-art metal-gate MOS transistor.

FIG. 5 is a cross-sectional view illustrating an example of short-resistant metal-gate MOS transistor 500 in accordance with the present invention.

FIGS. 6A-6R are cross-sectional views illustrating an example of a method 600 of forming a short-resistant metal-gate MOS transistor in accordance with the present invention.

FIG. 7 is a cross-sectional view illustrating an example of a short-resistant metal-gate MOS transistor 700 in accordance with an alternate embodiment of the present invention.

FIGS. 8A-8C are cross-sectional views illustrating an example of a method 800 of forming a short-resistant metal-gate MOS transistor in accordance with the present invention.

FIG. 9 is a cross-sectional view illustrating an example of a short-resistant metal-gate MOS transistor 900 in accordance with an alternate embodiment of the present invention.

FIG. 10 is a cross-sectional view illustrating an example of a transistor structure 1000 in accordance with an alternate embodiment of the present invention.

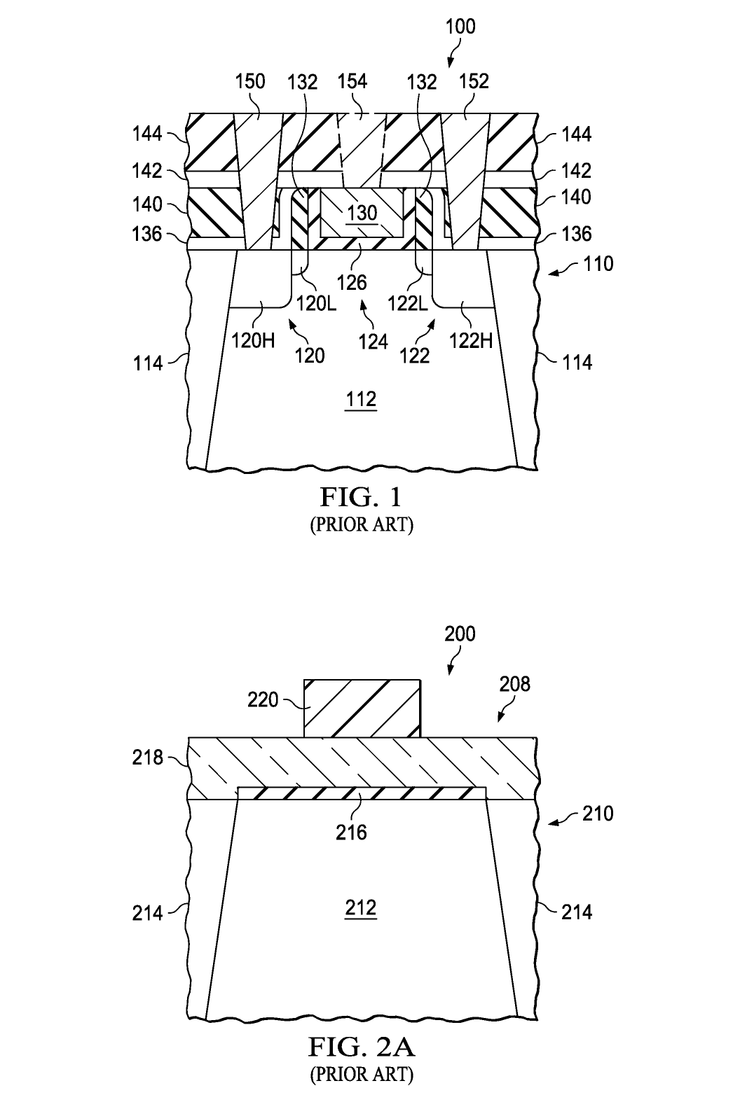

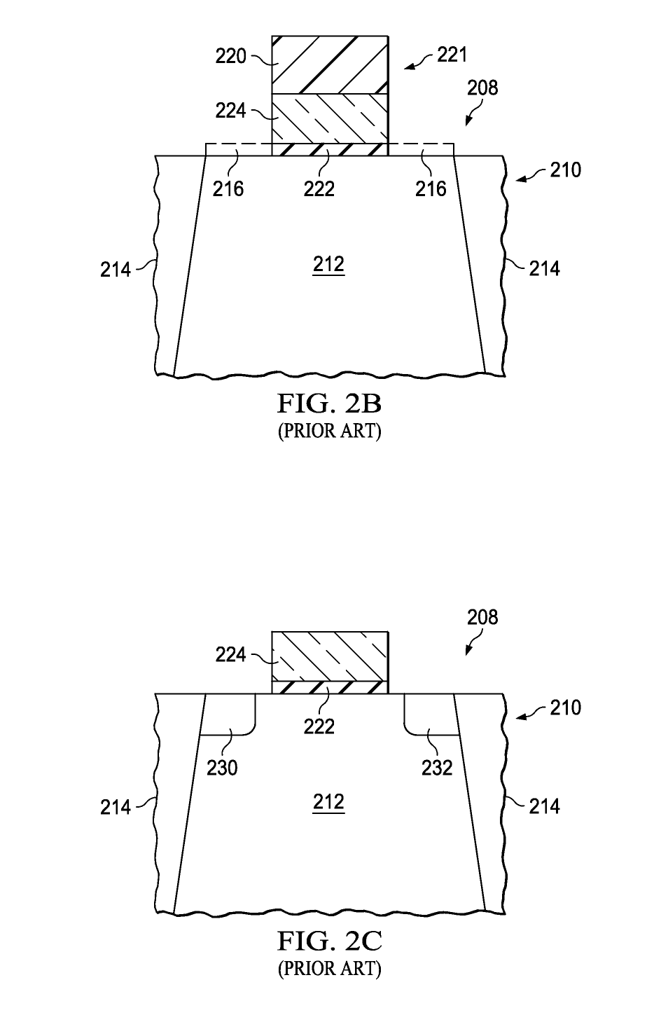

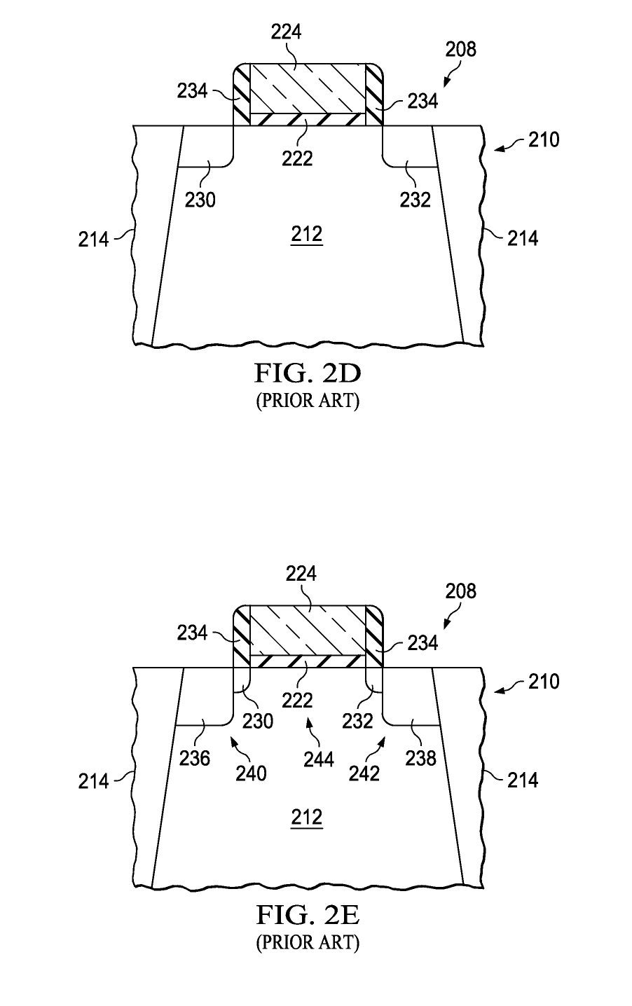

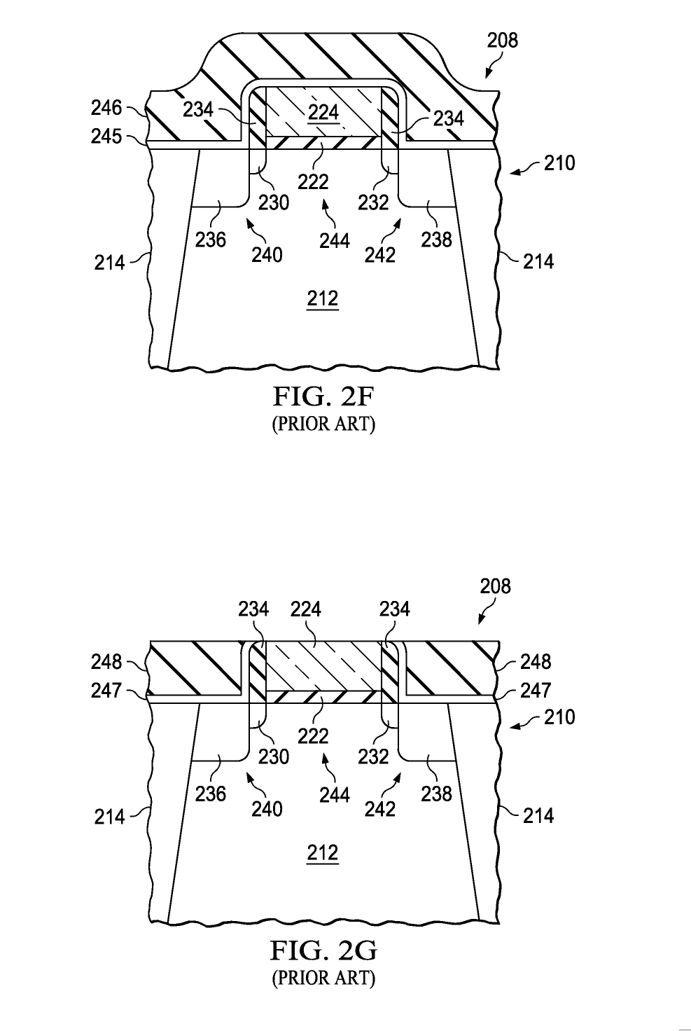

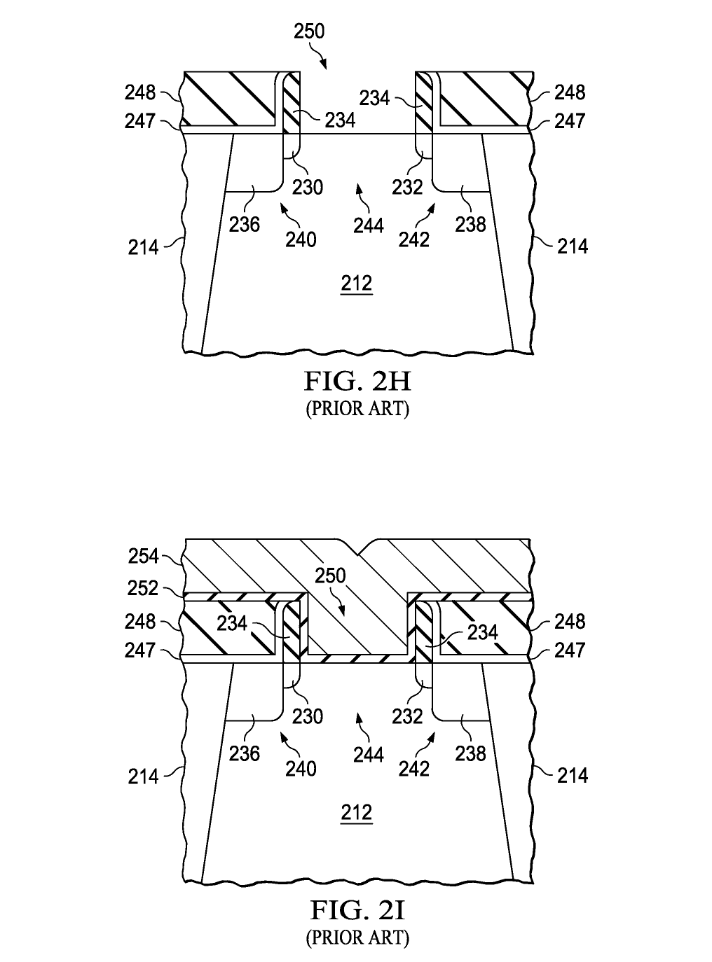

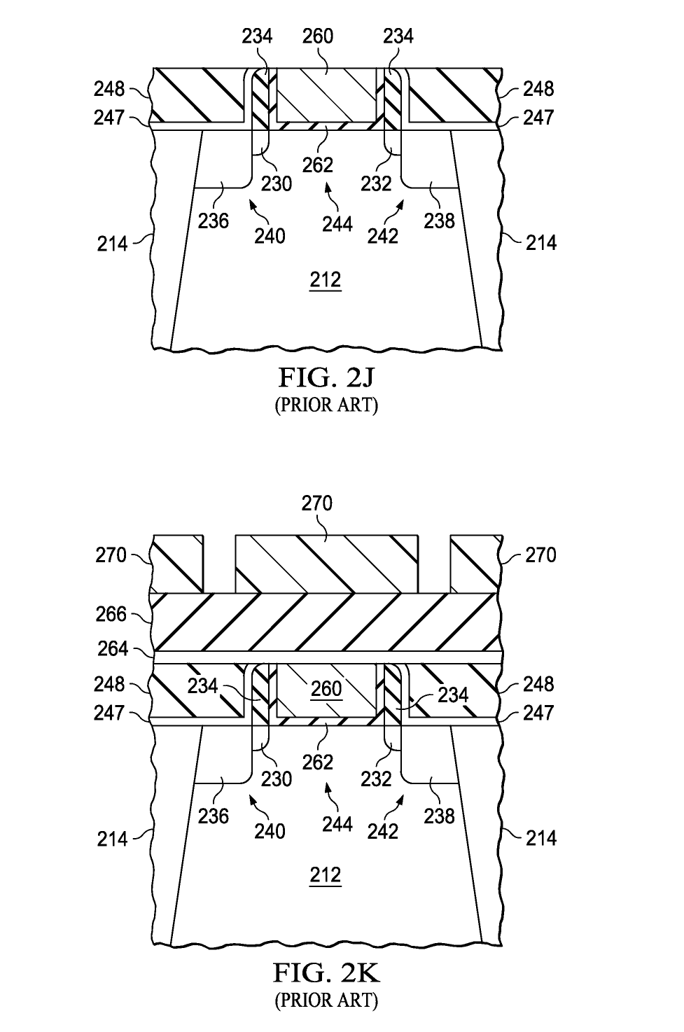

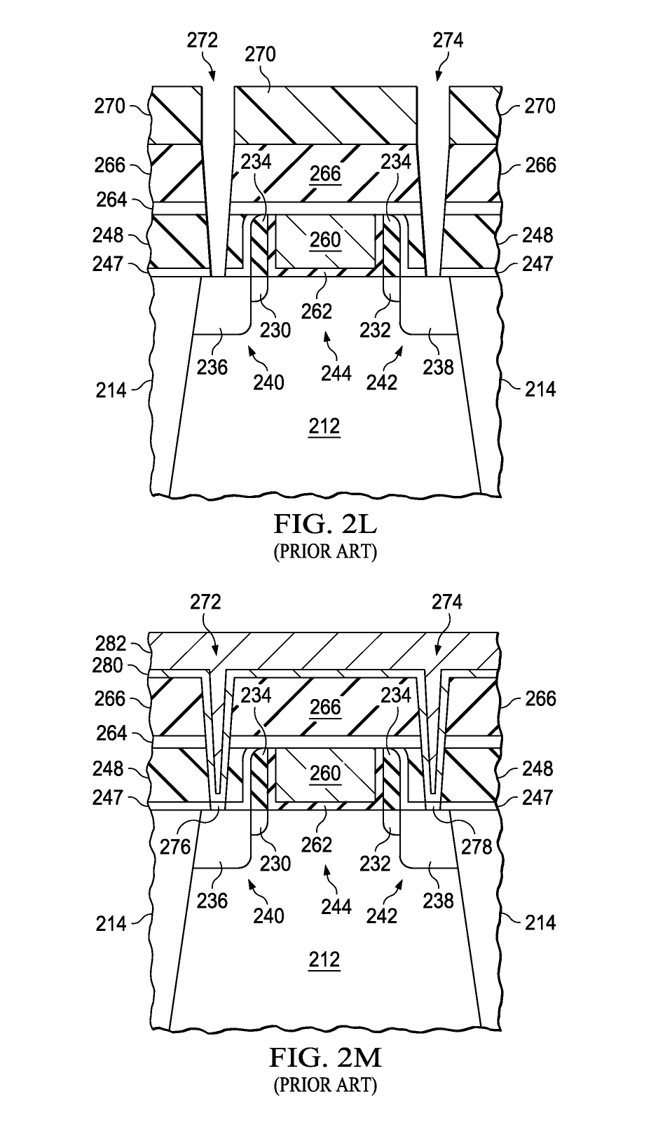

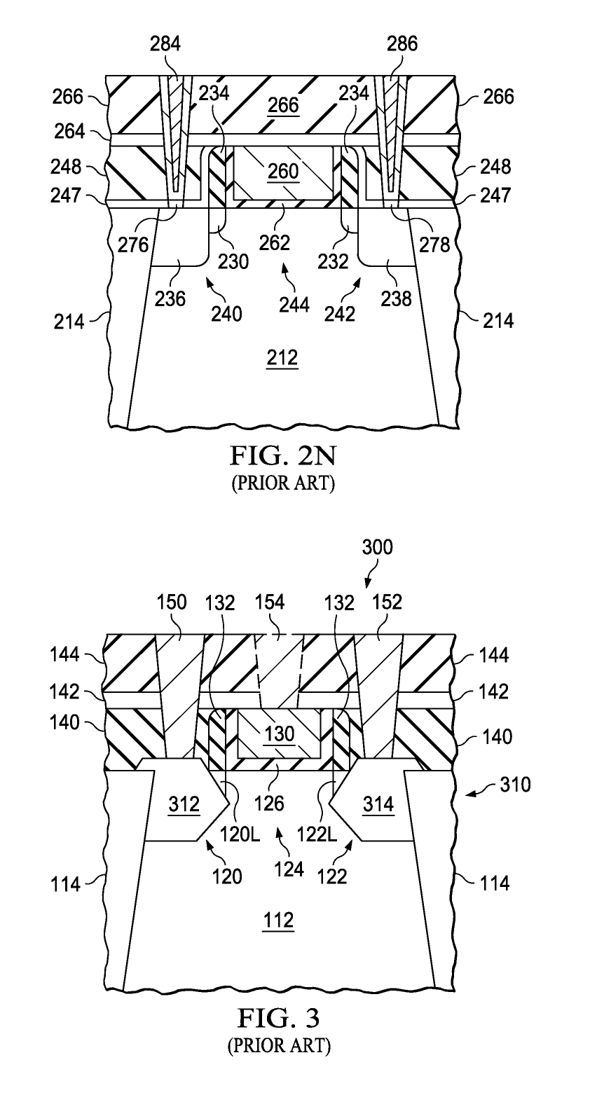

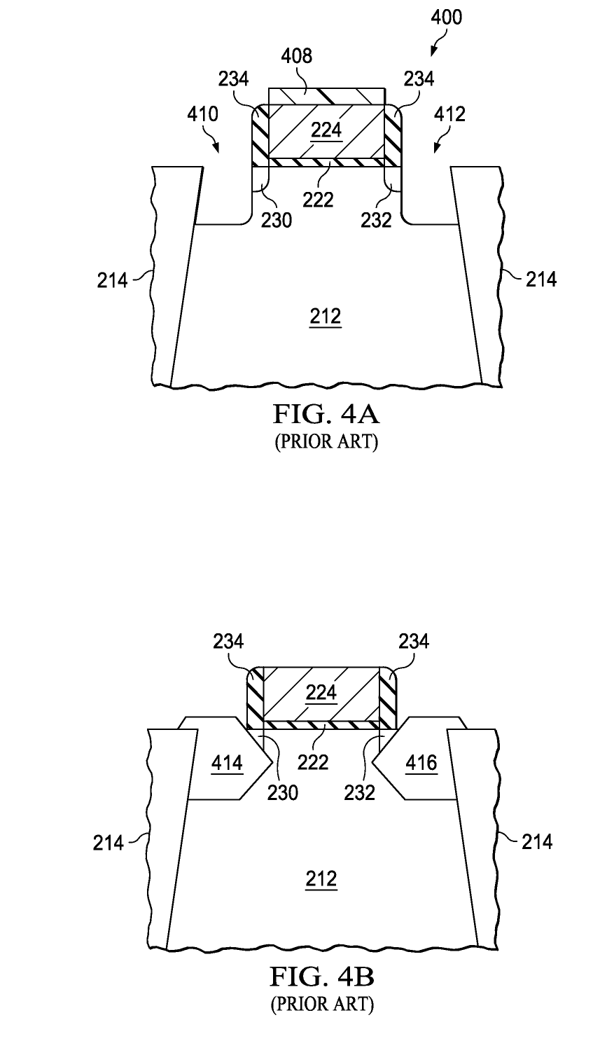

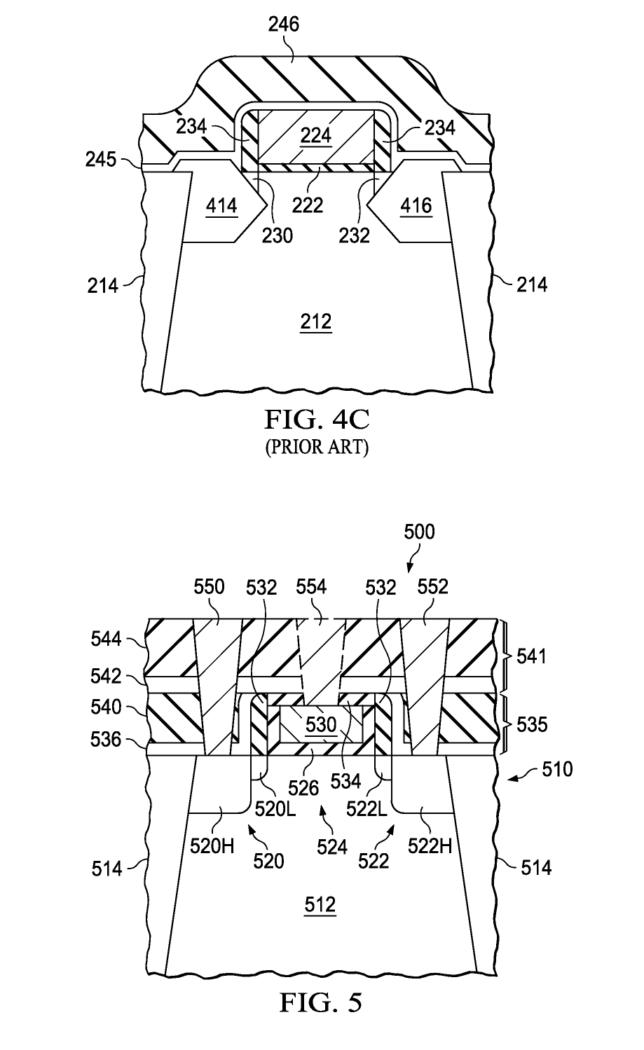

### DETAILED DESCRIPTION OF THE INVENTION

FIG. 5 shows a cross-sectional view that illustrates an example of a short-resistant metal-gate MOS transistor 500 in accordance with the present invention. As described in greater detail below, the present invention forms a protective cap over the metal gate of a MOS transistor. The protective cap protects the metal gate during the etch that forms a source contact opening and a drain contact opening. The protective cap also electrically isolates a source metal contact and a drain metal contact from the metal gate.

As shown in FIG. 5, MOS transistor 500 includes a semiconductor body 510. Semiconductor body 510, in turn, includes a single-crystal-silicon substrate region 512, and a trench isolation structure 514 that touches substrate region 512. In addition, semiconductor body 510 includes a source 520 and a drain 522 that each touch substrate region 512.

The source 520 and drain 522, which are spaced apart, each has a conductivity type that is the opposite of the conductivity type of substrate region 512. Source 520 includes a lightly-doped region 520L, and a heavily-doped region 520H. Similarly, drain 522 includes a lightly-doped region 522L, and a heavily-doped region 522H. Further, substrate region 512 has a channel region 524 that lies between source 520 and drain 522.

As further shown in FIG. 5, MOS transistor 500 includes a high-k gate dielectric structure 526 that touches and lies over channel region 524, and a metal gate 530 that touches gate dielectric structure 526 and lies over channel region 524. High-k gate dielectric structure 526 can be implemented with a number of materials, such as sequential layers of hafnium oxide and hafnium silicon oxide. Metal gate 530 can be implemented with a number of materials, such as sequential layers of titanium nitride, tantalum nitride, and aluminum.

MOS transistor 500 also includes a sidewall spacer 532 that touches high-k gate dielectric structure 526 and laterally surrounds gate 530. Sidewall spacer 532 can be implemented with a number of materials, such as oxide and nitride. Sidewall spacer 532 can also include a number of individual sidewall spacers that touch each other, such as an oxide sidewall spacer that touches a nitride (with thin oxide underliner) sidewall spacer. MOS transistor 500 additionally includes a protective cap 534 that touches and lies over gate 530. Protective cap 534, which is laterally surrounded by sidewall spacer 532, can be implemented with a number of materials, such as materials that include nitride.

In addition, MOS transistor 500 includes a non-conductive interconnect dielectric structure 535 that touches sidewall spacer 532. In the present example, dielectric structure 535 is implemented with an etch stop layer 536, and a dielectric layer 540 that touches and lies over etch stop layer 536. Etch stop layer 536 can each be implemented with a number of materials, such as silicon nitride or silicon oxynitride. Dielectric layer 540 can be implemented with a number of materials, such as oxide.

Further, MOS transistor 500 includes a non-conductive interconnect dielectric structure 541 that touches and lies over dielectric structure 535. In the present example, dielectric structure 541 is implemented with an etch stop layer 542 that touches and lies over dielectric layer 540, and a dielectric layer 544 that touches and lies over etch stop layer 542. Etch stop layer 542 can each be implemented with a number of materials, such as silicon nitride or silicon oxynitride. Dielectric layer 544 can be implemented with a number of materials, such as oxide.

Further, MOS transistor 500 includes a source metal contact 550 that extends through the first and second dielectric structures 535 and 541 (second dielectric layer 544, etch stop layer 542, first dielectric layer 540, and etch stop layer 536 in the present example) to touch and make an electrical connection to source 520. MOS transistor 500 also includes a drain metal contact 552 that extends through the first and second dielectric structures 535 and 541 (second dielectric layer 544, etch stop layer 542, first dielectric layer 540, and etch stop layer 536 in the present example) to touch and make an electrical connection to drain 522.

MOS transistor 500 further includes a gate metal contact 554 that extends through second dielectric structure 541 (second dielectric layer 544 and etch stop layer 542 in the present example) and protective cap 534 to touch and make an electrical connection with metal gate 530. Gate metal contact 554 is shown with dashed lines because gate metal contact 554 lies in a cross-sectional plane that lies behind the cross-sectional plane of FIG. 5. MOS transistor 500 operates substantially the same as MOS transistor 100.

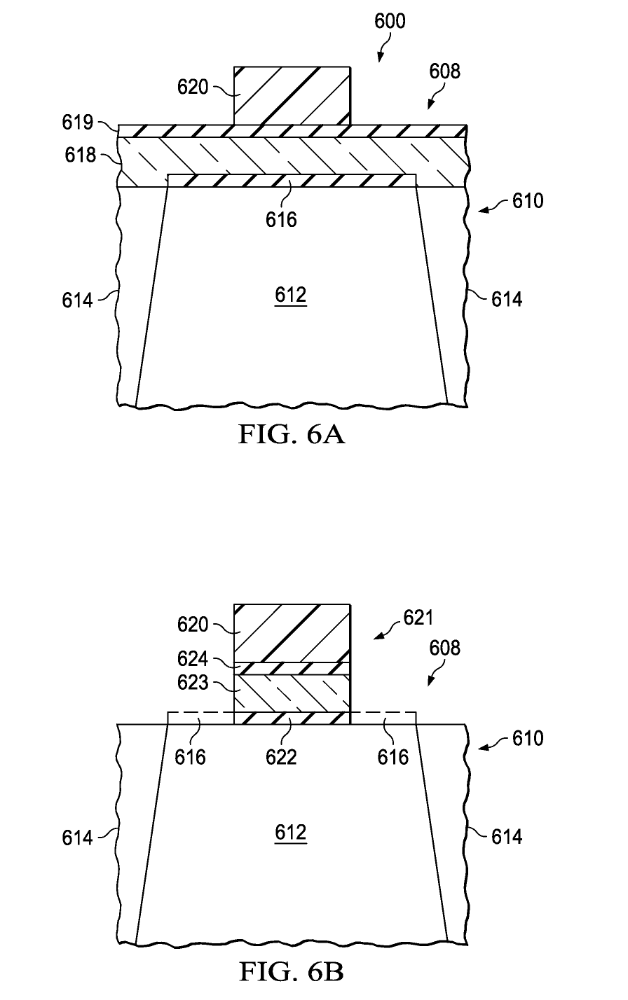

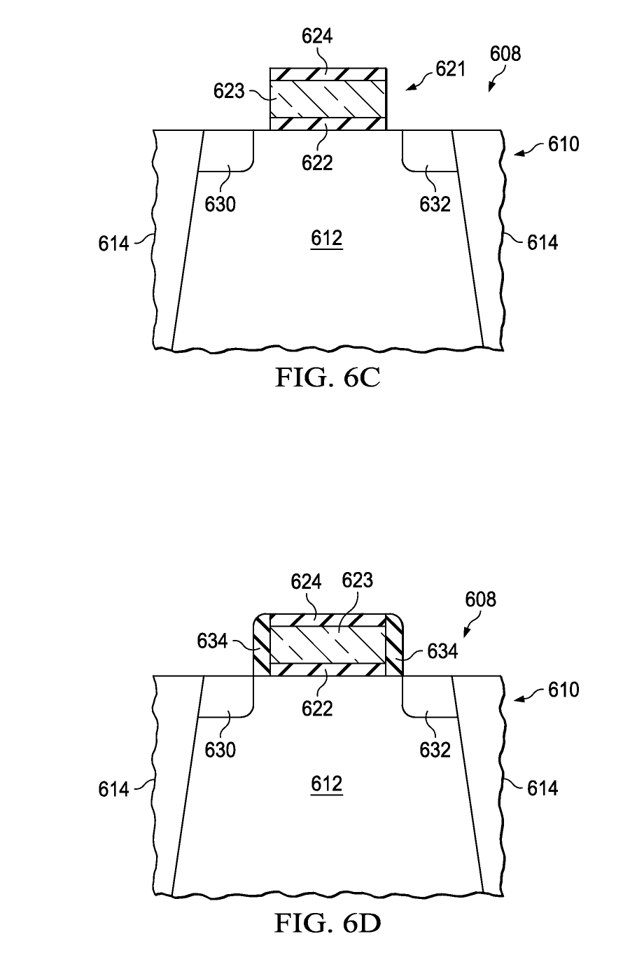

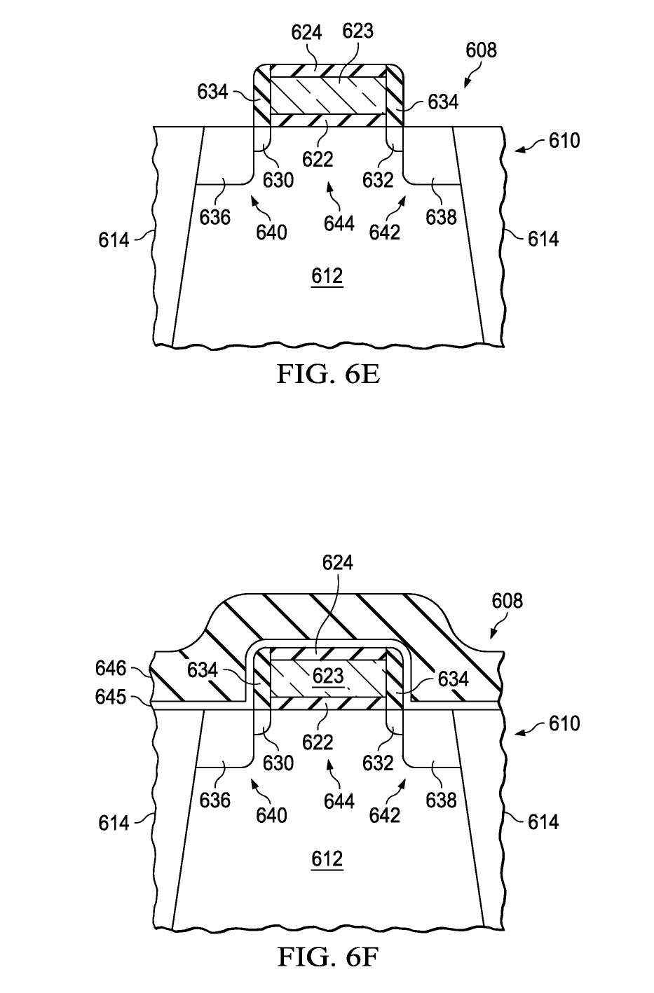

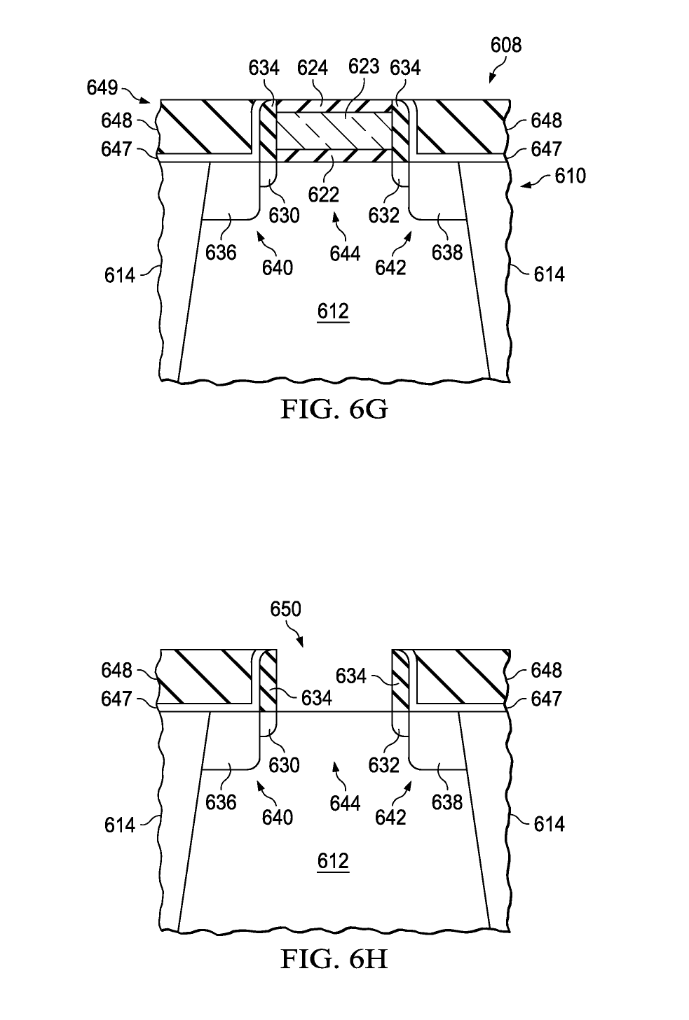

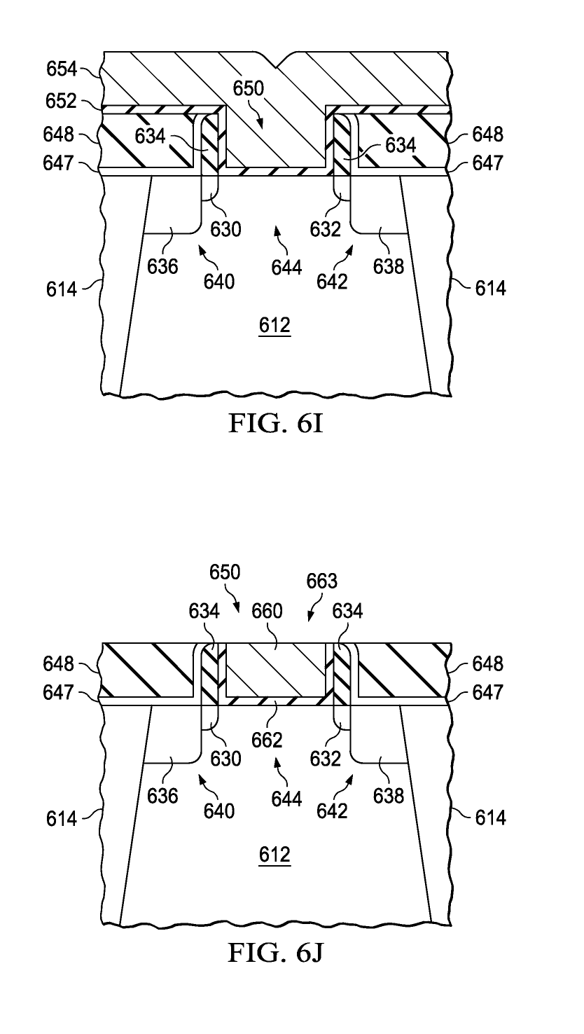

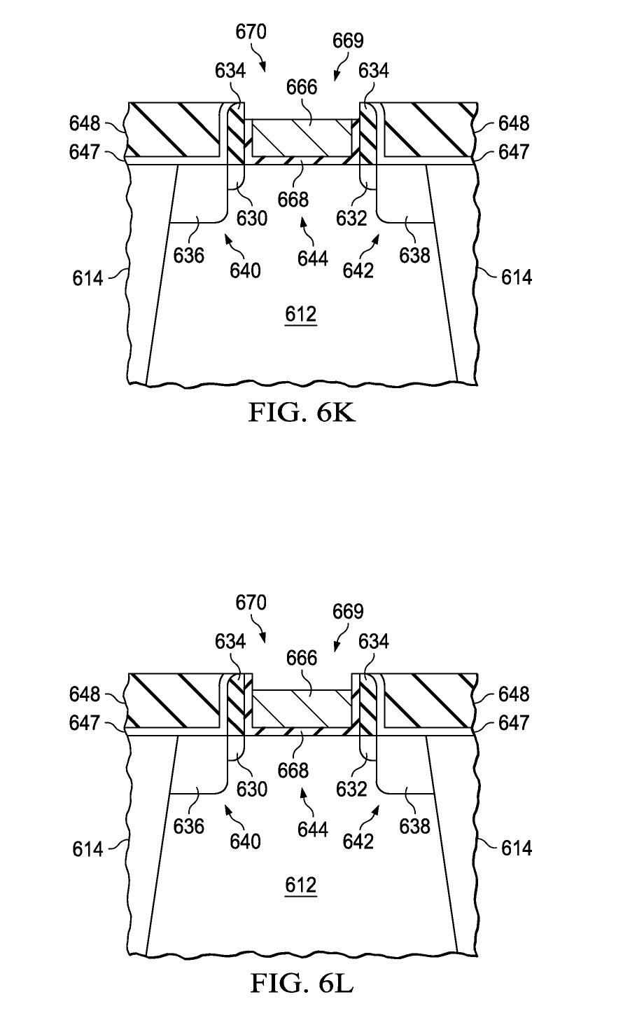

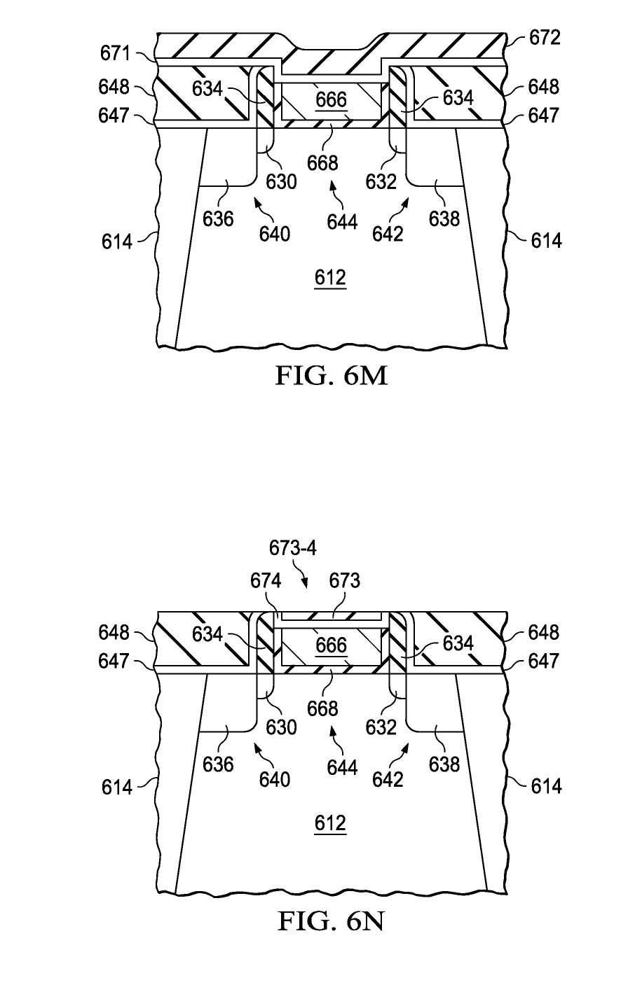

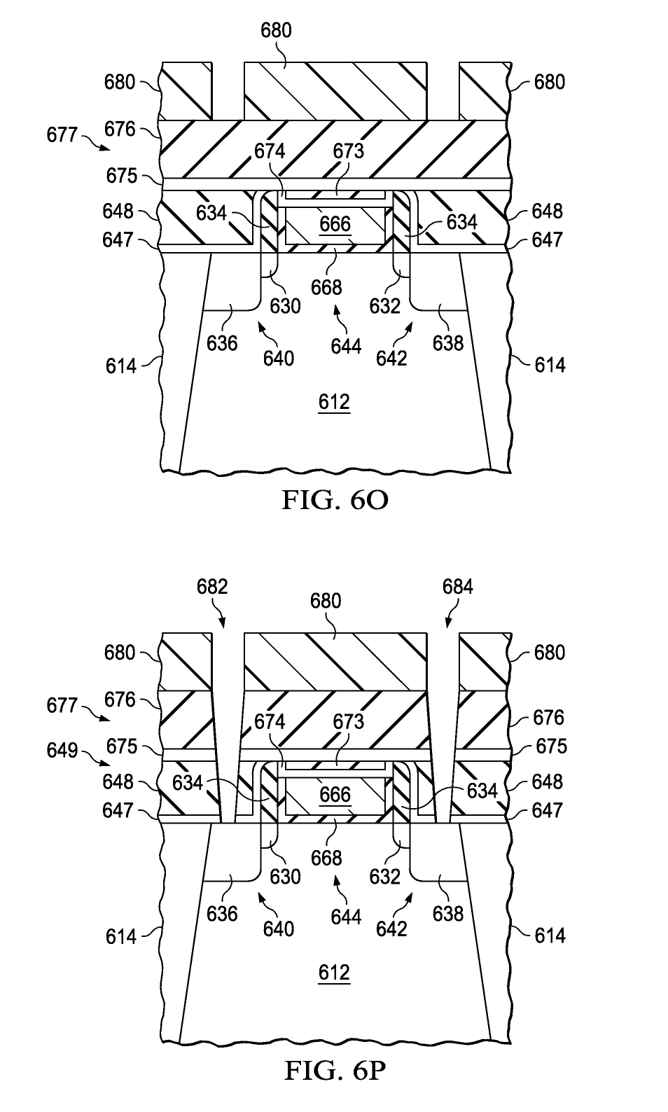

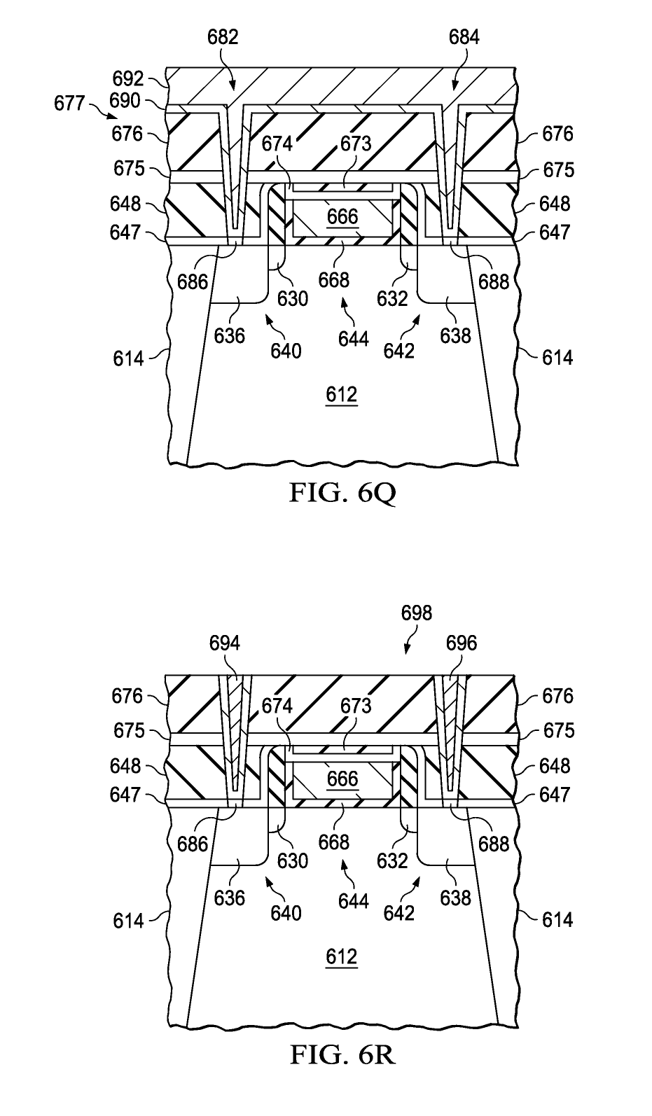

FIGS. 6A-6R show cross-sectional views that illustrate an example of a method 600 of forming a short-resistant metal-gate MOS transistor in accordance with the present invention. As shown in FIG. 6A, method 600 utilizes a partially-completed conventionally-formed transistor structure 608 that includes a semiconductor body 610. Semiconductor body 610, in turn, includes a single-crystal-silicon substrate region 612 and a trench isolation structure 614 that touches substrate 612.

As further shown in FIG. 6A, method 600 begins by conventionally forming a gate dielectric layer 616 to touch and lie over substrate region 612. Next, a gate layer 618 is formed to touch and lie over gate dielectric layer 616. Following this, a protective layer 619 is conventionally formed on gate layer 618. Gate dielectric layer 616 can be implemented with a number of materials, such as oxide, while gate layer 618 can be implemented with a number of sacrificial materials, such as polycrystalline silicon. Protective layer 619 can be implemented with a number of materials, such as nitride.

Following this, a patterned mask 620 is conventionally formed on protective layer 619. A patterned mask can be implemented in a number of ways, such as a hard mask or a patterned photoresist layer. (A hard mask is commonly formed by depositing a layer of oxide followed by an overlying layer of nitride. A patterned photoresist layer is next formed on the nitride layer, and the exposed regions of the nitride layer are then etched. The patterned photoresist layer is removed after the etch to form the hard mask.)

As shown in FIG. 6B, after patterned mask 620 has been formed, the exposed regions of protective layer 619, gate layer 618, and gate dielectric layer 616 are etched away in a conventional manner to expose the top surface of substrate region 612 and form a gate structure 621. Gate structure 621, in turn, includes a sacrificial gate dielectric structure 622 that touches and lies above substrate region 612, a sacrificial gate 623 that touches and lies over sacrificial gate dielectric structure 622, and a sacrificial protective cover 624 that touches and lies over sacrificial gate 623. (Protective layer 619 and sacrificial protective cover 624 can optionally be omitted.)

In an alternate embodiment, a portion of gate dielectric layer 616 can remain after the etch as illustrated by the dashed lines in FIG. 6B. In this case, gate structure 621 includes gate dielectric layer 616, sacrificial gate 623, and sacrificial protective cover 624. Following the etch, patterned mask 620 is removed in a conventional manner.

After patterned mask 620 has been removed, source and drain regions and a sidewall spacer are formed. The source and drain regions and the sidewall spacer can be formed in a number of different ways. In the present example, as shown in FIG. 6C, a dopant is next implanted into substrate region 612 in a conventional fashion to form spaced-apart lightly-doped regions 630 and 632. The lightly-doped regions 630 and 632 have a conductivity type that is opposite to the conductivity type of substrate region 612.

As shown in FIGS. 6D, after the lightly-doped regions 630 and 632 have been formed, a thin layer of oxide is formed, followed by the deposition of a thicker layer of nitride. Following this, the nitride layer and the thin layer of oxide are anisotropically etched until the top surface of sacrificial protective cover 624 is exposed to form a side wall spacer 634.

As shown in FIG. 6E, after sidewall spacer 634 has been formed, a dopant is implanted into substrate region 612 and the lightly-doped regions 630 and 632 in a conventional fashion to form spaced-apart heavily-doped regions 636 and 638. The heavily-doped regions 636 and 638 each have a conductivity type that is opposite to the conductivity type of substrate region 612.

Lightly-doped region 630 and heavily-doped region 636 form a source 640, while lightly-doped region 632 and heavily-doped region 638 form a drain 642. The source and drain regions 640 and 642 define a channel region 644 of substrate region 612 that lies between and separates the source and drain regions 640 and 642.

In a first alternate embodiment, a pre-implant sidewall spacer can be formed after gate structure 621 has been formed and before the lightly-doped regions 630 and 632 have been formed by depositing a non-conductive layer, such as oxide, on gate structure 621 and then anisotropically etching the non-conductive layer until the top surface of sacrificial protective cover 624 is exposed.

In a second alternate embodiment, the implant that forms the lightly-doped source and drain regions can be performed after sidewall spacer 634 has been formed and before the heavily-doped regions 636 and 638 have been formed. In this embodiment, a post-implant sidewall spacer is formed after the lightly-doped regions 630 and 632 have been formed and before the heavily-doped regions 636 and 638 have been formed by depositing a non-conductive layer, such as oxide, on spacer 634 and gate structure 621, and then anisotropically etching the non-conductive layer until the top surface of sacrificial protective cover 624 is exposed. Following this, the implant that forms the heavily-doped source and drain regions is performed.

As shown in FIG. 6F, after the source and drain regions 640 and 642 and sidewall spacer 634 have been formed, an etch stop layer 645 is formed in a conventional manner to touch and lie over sacrificial protective cover 624, sidewall spacer 634, source region 640, and drain region 642. Following this, a dielectric layer 646 is formed to touch and lie over etch stop layer 645. Etch stop layer 645 can be implemented with a number of materials, such as silicon nitride or silicon oxynitride, while dielectric layer 646 can be implemented with a number of materials, such as oxide.

As shown in FIG. 6G, after dielectric layer 646 has been formed, dielectric layer 646 is planarized, such as with chemical-mechanical polishing, until the top surface of etch stop layer 645 is detected. Following this, etch stop layer 645 and dielectric layer 646 are planarized until the top surface of sacrificial protective cover 624 has been exposed.

The planarization forms an etch stop structure 647 that touches sidewall spacer 634, and a dielectric structure 648 that touches etch stop structure 647. Etch stop structure 647 and dielectric structure 648, which are both non-conductive, form a non-conductive interconnect dielectric structure 649 that touch sidewall spacer 634. (Etch stop layer 645 and etch stop structure 647 can be optionally omitted.) As a result of the planarization, the top surfaces of sacrificial protective cover 624 and dielectric structure 649 lie substantially in the same plane.

As shown in FIG. 6H, after the top surface of sacrificial protective cover 624 has been exposed, sacrificial protective cover 624 is removed using conventional etchants and procedures. Following this, sacrificial gate 623 is removed using conventional etchants and procedures. Next, sacrificial gate dielectric structure 622 is removed using conventional etchants and procedures to form an opening 650 that exposes the top surface of channel region 644.

As shown in FIG. 6I, after opening 650 has been formed, a high-k dielectric layer 652 is formed in a conventional manner to line opening 650 and touch the top surfaces of channel region 644 and dielectric structure 648. High-k gate dielectric layer 652 can be implemented with a number of materials, such as a layer of hafnium oxide and a layer of hafnium silicon oxide that overlies the layer of hafnium oxide.

Next, a metal layer 654 is conventionally deposited to touch high-k dielectric layer 652 and fill up opening 650. Metal layer 654 can be implemented with a number of materials that each partially fill up opening 650, such as a layer of titanium nitride, a layer of tantalum nitride that overlies the layer of titanium nitride, and a layer of aluminum that overlies the layer of tantalum nitride.

As shown in FIG. 6J, after metal layer 654 has been deposited, metal layer 654 and high-k dielectric layer 652 are planarized, such as with chemical-mechanical polishing, until the top surface of dielectric structure 648 has been exposed. The planarization forms a metal gate 660 and a high-k dielectric structure 662 that touches metal gate 660 and channel region 644 in opening 650. As a result of the planarization, the top surfaces of dielectric structure 648, metal gate 660, and high-k dielectric structure 662 lie substantially in the same plane. Metal gate 660 and high-k dielectric structure 662 form a second gate structure 663.

As shown in FIG. 6K, after metal gate 660 and high-k dielectric structure 662 have been formed, metal gate 660 is etched using a conventional etch chemistry that is selective to metal for a predetermined period of time to form a metal gate 666. Following this, high-k dielectric structure 662 is etched using a conventional etch chemistry that is selective to the dielectric for a predetermined period of time to form a high-k dielectric structure 668 that touches metal gate 666 and channel region 644.

Metal gate 666 and a high-k dielectric structure 668 form a third gate structure 669. In addition, the removal of part of gate 660 and high-k dielectric structure 662 forms an opening 670 that lies over metal gate 666. In an alternate embodiment, as shown in FIG. 6L, the etch of high-k dielectric structure 662 can be omitted. In this case, third gate structure 669 includes metal gate 666 and high-k dielectric structure 662, while opening 670 is formed from the removal of part of gate 660.

As shown in FIG. 6M, after opening 670 has been formed, an etch stop layer 671 is formed in a conventional manner to touch and lie over gate 666 and dielectric structure 648. Etch stop layer 671 can be implemented with a number of materials, such as silicon nitride or silicon oxynitride. Following this, a protective layer 672 is formed in a conventional manner to fill up opening 670 and touch the top surface etch stop layer 671. Protective layer 672 can be implemented with a number of materials, such as nitride.

As shown in FIG. 6N, after protective layer 672 has been deposited, protective layer 672 is planarized, such as with chemical-mechanical polishing, until the top surface of etch stop layer 671 has been exposed. After this, protective layer 672 and etch stop layer 671 are planarized until dielectric structure 648 has been exposed.

The planarization forms a protective structure 673, and an etch stop structure 674 that touches protective structure 673 and gate 666. As a result of the planarization, the top surfaces of dielectric structure 648, protective structure 673, and etch stop structure 674 lie substantially in the same plane. Protective structure 673 and etch stop structure 674, which are both non-conductive, form a protective cap 673-4. (Etch stop layer 671 and etch stop structure 674 can be optionally omitted.)

As shown in FIG. 60, after protective structure 673 has been formed, an etch stop layer 675 is conventionally formed to touch dielectric structure 648 and protective structure 673. Etch stop layer 675 can be implemented with a number of materials, such as silicon nitride or silicon oxynitride. Following the formation of etch stop layer 675, a dielectric layer 676 is formed on etch stop layer 675 in a conventional fashion. Dielectric layer 676 can be implemented with a number of materials, such as oxide.

Etch stop layer 675 and dielectric layer 676, which are both non-conductive, form a non-conductive interconnect dielectric structure 677. (Etch stop layer 675 can be optionally omitted.) After dielectric layer 676 has been formed, a source/drain patterned mask 680 is conventionally formed on dielectric layer 676.

As shown in FIG. 6P, after source/drain patterned mask 680 has been formed, the exposed regions of interconnect dielectric structure 649 and interconnect dielectric structure 677 (dielectric layer 676, etch stop layer 675, dielectric structure 648, and etch stop layer 647 in the present example) are etched away in a conventional manner to form a source contact opening 682 that exposes the top surface of source 640, and a drain contact opening 684 that exposes the top surface of drain 642. Source/drain patterned mask 680 is then removed in a conventional fashion.

After source/drain patterned mask 680 has been removed, a gate patterned mask is conventionally formed on dielectric layer 676. After the gate patterned mask has been formed, the exposed regions of interconnect dielectric structure 677 (dielectric layer 676 and etch stop layer 675 in the present example), protective structure 673, and etch stop structure 674 are etched away in a conventional manner to form a gate contact opening (not shown) that exposes the top surface of gate 666. The gate patterned mask is then removed in a conventional fashion.

As shown in FIG. 6Q, after the gate patterned mask has been removed, a source silicide region 686 is conventionally formed on the top surface of source 640, and a drain silicide region 688 is conventionally formed on the top surface of drain 642. Next, a barrier metal layer 690 is conventionally deposited on interconnect dielectric structure 677 to line source contact opening 682 and touch source silicide region 686, line drain contact opening 684 and touch drain silicide region 688, and line the gate contact opening and touch gate 666.

Barrier metal layer 690 can be implemented with, for example, titanium nitride or tantalum nitride. Following this, a metal layer 692 is deposited in a conventional manner on barrier metal layer 690 to fill up the source contact opening 682, the drain contact opening 684, and the gate contact opening. Metal layer 692 can be implemented with a number of materials, such as tungsten or copper.

As shown in FIG. 6R, after metal layer 692 has been deposited, metal layer 692 and barrier metal layer 690 are planarized, such as with chemical-mechanical polishing, until the top surface of dielectric layer 676 has been exposed. The planarization forms a source metal contact 694 that touches source 640, a drain metal contact 696 that touches drain 642, and a gate metal contact that touches gate 666. In addition, the planarization also forms a short-resistant metal-gate MOS transistor 698. Following this, method 600 continues with conventional steps.

One of the advantages of the present invention is that when the source contact opening 682 is misaligned, the source contact opening 682 does not expose any portion of gate 666 because protective structure 673 protects the top surface of gate 666 from the etch that forms the source contact opening 682.

Similarly, when the drain contact opening 684 is misaligned, the drain contact opening 684 does not expose any portion of gate 666 because protective structure 673 protects the top surface of gate 666 from the etch that forms the drain contact opening 684. Thus, since gate 666 is covered by protective structure 673, transistor 698 is resistant to a source-to-gate or a drain-to-gate short. In addition, protective structure 673 also electrically isolates source metal contact 694 and drain metal contact 696 from metal gate 666.

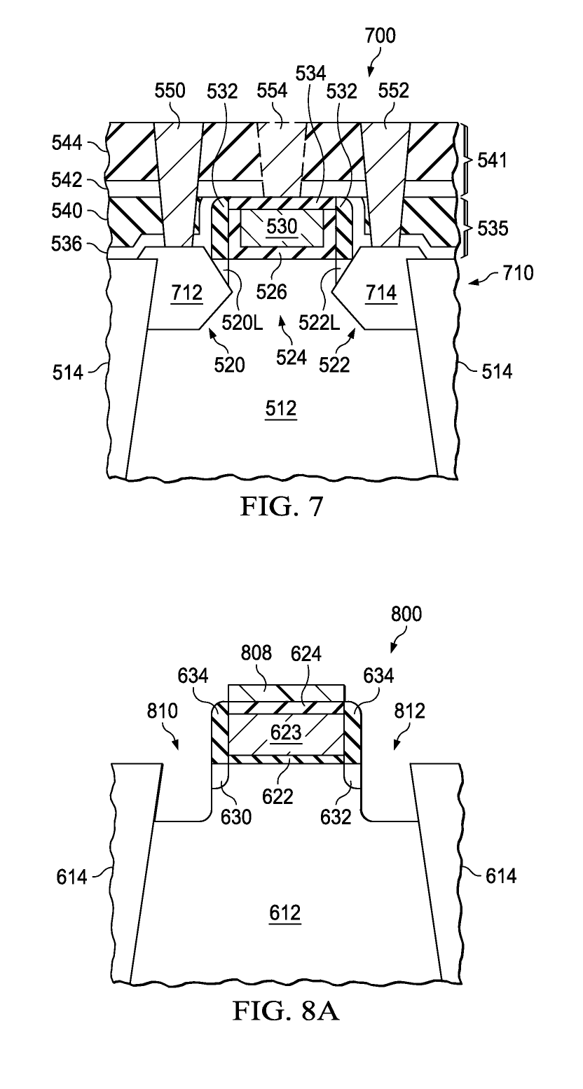

FIG. 7 shows a cross-sectional view that illustrates an example of a short-resistant metal-gate MOS transistor 700 in accordance with an alternate embodiment of the present invention. MOS transistor 700 is similar to MOS transistor 500 and, as a result, utilizes the same reference numerals to designate the structures that are common to both transistors 500 and 700.

As shown in FIG. 7, MOS transistor 700 differs from MOS transistor 500 in that MOS transistor 700 utilizes a semiconductor body 710 in lieu of semiconductor body 510. Semiconductor body 710, in turn, is the same as semiconductor body 510 except that semiconductor body 710 utilizes a heavily-doped epitaxially-grown structure 712 in lieu of heavily-doped single-crystal-silicon region 520H, and a heavily-doped epitaxially-grown structure 714 in lieu of heavily-doped single-crystal-silicon region 522H. The epitaxially-grown structures 712 and 714 have a conductivity type that is opposite to the conductivity type of substrate region 512.

Thus, in metal-gate MOS transistor 700, lightly-doped region 520L and heavily-doped epitaxially-grown structure 712 form source 520, while lightly-doped region 522L and heavily-doped epitaxially-grown structure 714 form drain 522. The epitaxially-grown structures 712 and 714 can be implemented with, for example, silicon germanium (PMOS) or silicon carbide (NMOS).

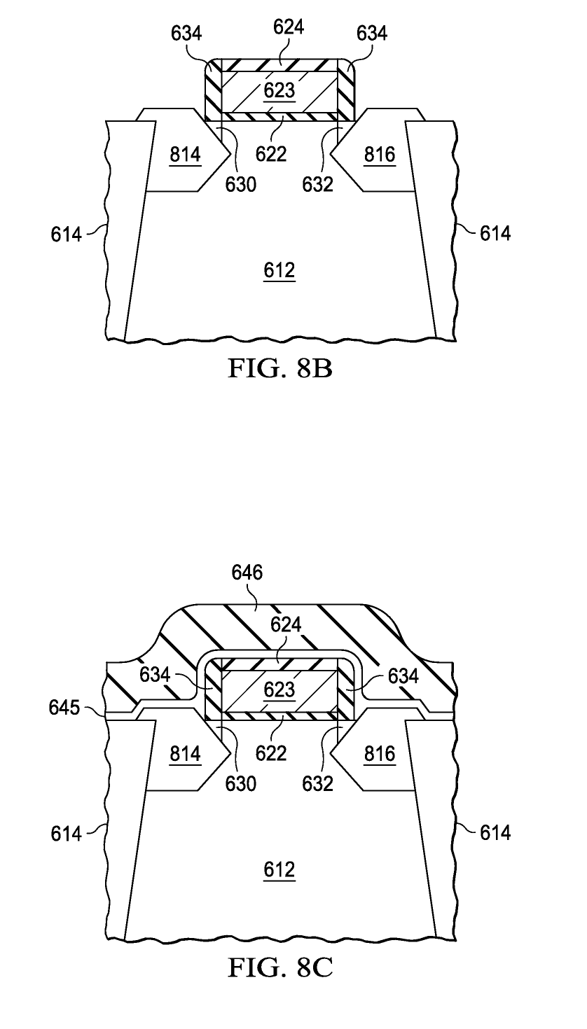

FIGS. 8A-8C show cross-sectional views that illustrate an example of a method 800 of forming a short-resistant metal-gate MOS transistor in accordance with the present invention. Method 800 is the same as method 600 up through the formation of sidewall spacer 634 shown in FIG. 6D. As shown in FIG. 8A, after side wall spacer 634 has been formed, a patterned mask 808 is formed on sacrificial gate 623. (Patterned mask 808 can be optionally omitted due to the presence of sacrificial protective cover 624.) Following this, the exposed portions of substrate region 612 and the lightly-doped regions 630 and 632 are etched in a conventional manner to form a source opening 810 and a drain opening 812.

As shown in FIG. 8B, after source opening 810 and drain opening 812 have been formed, a heavily-doped structure 814 is epitaxially grown in source opening 810 at the same time that a heavily-doped structure 816 is epitaxially grown in drain opening 812. The epitaxially-grown structures 814 and 816, which are conventionally formed, each have a conductivity type that is opposite to the conductivity type of substrate region 612, and can be implemented with, for example, silicon germanium (PMOS) or silicon carbide (NMOS).

As shown in FIG. 8C, after the epitaxially-grown structures 814 and 816 have been formed, etch stop layer 645 is formed on sacrificial gate 623, sidewall spacer 634, and the epitaxially-grown structures 814 and 816 in the same manner that etch stop layer 645 was formed in method 600. Following this, method 800 is the same as method 600, and continues with the deposition of dielectric layer 646.

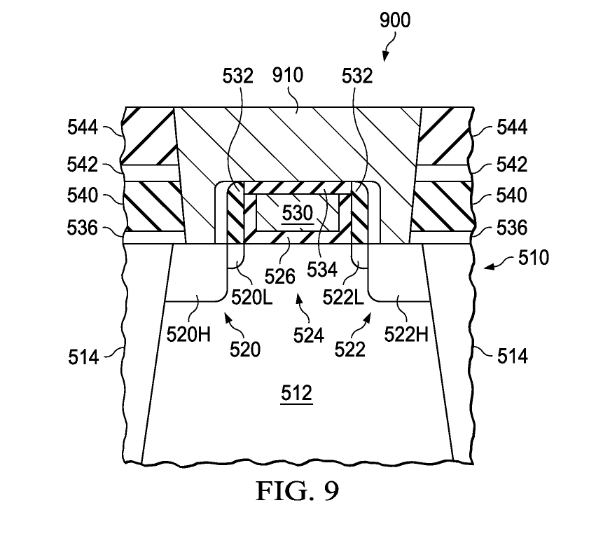

FIG. 9 shows a cross-sectional view that illustrates an example of a short-resistant metal-gate MOS transistor 900 in accordance with an alternate embodiment of the present invention. MOS transistor 900 is similar to MOS transistor 500 and, as a result, utilizes the same reference numerals to designate the structures that are common to both transistors 500 and 900.

As shown in FIG. 9, MOS transistor 900 differs from MOS transistor 500 in that MOS transistor 900 utilizes a flyover metal contact 910 in lieu of source metal contact 550 and drain metal contact 552. Flyover metal contact 910, which is insulated from gate 530 by protective cap 534, provides a simple way of electrically connecting active regions using contact metal as a local interconnect, as illustrated by connecting source 520 to drain 522. Method 600 can be used to form flyover metal contact 910 by modifying patterned mask 680 shown in FIG. 6O to have a single continuous opening that lies over both source 640 and drain 642.

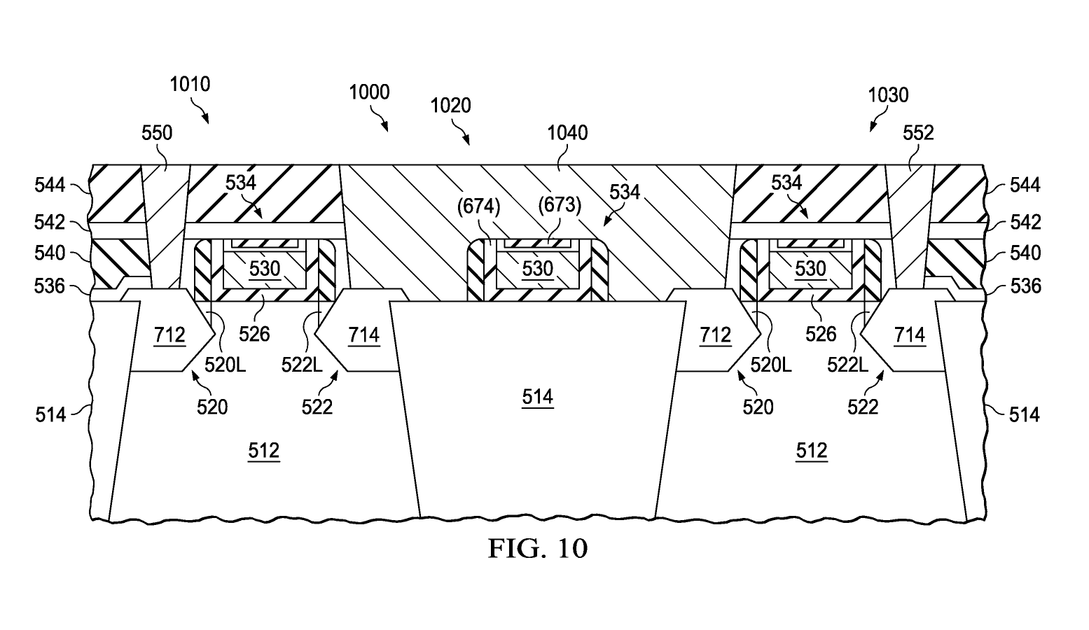

FIG. 10 shows a cross-sectional view that illustrates an example of a transistor structure 1000 in accordance with an alternate embodiment of the present invention. As shown in FIG. 10, transistor structure 1000 includes a first transistor 1010, a second transistor 1020, and a third transistor 1030. First transistor 1010 is substantially identical to transistor 700 (differing with reference to FIG. 6 in that transistor 1010 shows the alternate embodiment where high-k dielectric structure 662 is not etched when gate 660 is etched back). Second transistor 1012 is identical to transistor 500, but shows in the FIG. 10 cross section a portion of transistor 500 that lies above trench isolation structure 514. Third transistor 1014 is identical to transistor 1010.

As further shown in FIG. 10, transistor structure 1000 includes a flyover metal contact 1040 that replaces drain metal contact 552 of transistor 1010 and source metal contact 550 of transistor 1030. Flyover metal contact 1040, which is insulated from gate 530 of transistor 1020 by protective cap 534, provides a simple way of electrically connecting drain 522 of transistor 1010 to source 520 of transistor 1030. Method 600 can be used to form flyover metal contact 1040 by modifying patterned mask 680 shown in FIG. 6O to have a single continuous opening that extends from the drain of transistor 1010 to the source of transistor 1030.

Thus, another of the advantages of the present invention is that, in addition to protecting gate 530, protective cap 534 also allows simple flyover metal contacts to be formed. The flyover metal contacts eliminate the need to route an electrical connection up through the metal interconnect structure which, in turn, reduces the interconnect resistance and simplifies the layout.

It should be understood that the above descriptions are examples of the present invention, and that various alternatives of the invention described herein may be employed in practicing the invention. Thus, it is intended that the following claims define the scope of the invention and that structures and methods within the scope of these claims and their equivalents be covered thereby.

What is claimed is:

1. A semiconductor structure comprising:
a semiconductor material having a conductivity type;
a source that touches the semiconductor material, the source having a conductivity type that is opposite to the conductivity type of the semiconductor material;
a drain that touches the semiconductor material, the drain lying spaced apart from the source, and having a conductivity type that is opposite to the conductivity type of the semiconductor material;
a channel region of the semiconductor material that lies between the source and the drain;
a gate dielectric structure that touches and lies over the channel region;
a metal gate that touches the gate dielectric structure and lies over the channel region;
a protective cap that touches and lies over the metal gate; and
a non-conductive sidewall spacer that touches the gate dielectric structure and laterally surrounds both the metal gate and the protective cap.

2. The semiconductor structure of claim 1 wherein the protective cap includes:
an etch stop structure that touches and lies over the metal gate; and
a protective structure that touches and lies over the etch stop structure.

3. The semiconductor structure of claim 1 wherein:
the source includes a lightly-doped region and a heavily-doped region that touch each other; and
the drain includes a lightly-doped region and a heavily-doped region that touch each other.

4. The semiconductor structure of claim 1 wherein:
the source includes a lightly-doped source region and an epitaxially-grown source structure that touches the lightly-doped source region; and
the drain includes a lightly-doped drain region and an epitaxially-grown drain region that touches the lightly-doped drain region.

5. The semiconductor structure of claim 4 wherein the epitaxially-grown source structure and the epitaxially-grown drain structure include silicon germanium.

6. The semiconductor structure of claim 4 wherein the epitaxially-grown source structure and the epitaxially-grown drain structure include silicon carbide.

7. The semiconductor structure of claim 1 and further comprising a flyover metal contact that touches and lies above the protective cap.

8. The semiconductor structure of claim 7 wherein the flyover metal contact touches the source and the drain.

9. The semiconductor structure of claim 7 wherein the flyover metal contact is spaced apart from the source and the drain.

10. The semiconductor structure of claim 1 and further comprising:
a first interconnect dielectric structure that touches and lies over the source; and
a second interconnect dielectric structure that touches and lies over the first interconnect dielectric structure.

11. The semiconductor structure of claim 10 and further comprising:
a source metal contact that extends through the first interconnect dielectric structure and the second interconnect dielectric structure to touch the source; and
a drain metal contact that extends through the first interconnect dielectric structure and the second interconnect dielectric structure to touch the drain.

12. The semiconductor structure of claim 10 wherein the first interconnect dielectric structure includes:
a first etch stop layer that touches and lies over the source; and
a first dielectric structure that touches and lies over the first etch stop layer.

13. The semiconductor structure of claim 12 wherein the second interconnect dielectric structure includes:
a second etch stop layer that touches and lies over the first dielectric structure; and
a second dielectric structure that touches and lies over the second etch stop layer.

14. The semiconductor structure of claim 13 and further comprising:
a source metal contact that extends through the second dielectric structure, the second etch stop layer, the first dielectric structure, and the first etch stop layer to touch the source; and
a drain metal contact that extends through the second dielectric structure, the second etch stop layer, the first dielectric structure, and the first etch stop layer to touch the drain.

15. The semiconductor structure of claim 1 wherein the gate dielectric structure includes a high-k material.

16. A method of forming a semiconductor structure comprising:
forming a first gate structure that touches a semiconductor material, the semiconductor material having a conductivity type;
forming a source and a drain that touch the semiconductor material, the source and the drain each having a conductivity type that is opposite the conductivity type of the semiconductor material;
forming a non-conductive structure that touches and lies over the source and the drain;
removing the first gate structure to form an opening after the first non-conductive structure has been formed;
forming a second gate structure in the opening to touch the semiconductor material;
etching the second gate structure to form a third gate structure; and
forming a protective cap that touches and lies over the third gate structure.

17. The method of claim 16 wherein the first gate structure includes:
a sacrificial gate dielectric structure that touches the semiconductor material;
a sacrificial gate that touches and lies above the sacrificial gate dielectric structure; and
a sacrificial protective cover that touches and lies above the sacrificial gate.

18. The method of claim 17 wherein the second gate structure includes a metal gate and a gate dielectric structure that touches and lies below the metal gate.

19. The method of claim 16 wherein etching the second gate structure includes etching the metal gate to form an etched gate.

20. The method of claim 19 wherein the protective cap includes:
an etch stop structure that touches and lies over the etched gate; and
a protective structure that touches and lies over the etch stop structure.
